(19) United States
(12) Patent Application Publication
(10) Pub. No.: US 2025/0311144 A1
(43) Pub. Date: Oct. 2, 2025

(54) PROACTIVE TEMPERATURE AND FAN SPEED BASED UTILITY QOS TRIGGERING

(71) Applicant: DELL PRODUCTS L.P., Round Rock, TX (US)

(72) Inventors: Travis C. North, Cedar Park, TX (US); Balasingh Samuel, Round Rock, TX (US); Suraj M Varma, Portland, OR (US)

(21) Appl. No.: 18/618,556

(22) Filed: Mar. 27, 2024

(51) Int. Cl. H05K 7/20

(52) U.S. Cl. CPC H05K 7/20209

(57) ABSTRACT

An information handling system includes a cooling device, a cooling device controller, and a cooling level estimator. The cooling device cools the information handling system. The cooling device controller controls a level of cooling for the information handling system based on a cooling profile provided by a cooling table. The cooling level estimator determines status information for the information handling system, and provides a quality of service (QOS) level indication to the cooling device controller. The cooling device controller modifies the cooling profile based on the QoS level indication.

### FIELD OF THE DISCLOSURE

This disclosure generally relates to information handling systems, and more particularly relates to proactively triggering quality of service levels based on component temperatures and fan speeds in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An information handling system may include a cooling device, a cooling device controller, and a cooling level estimator. The cooling device may cool the information handling system. The cooling device controller may control a level of cooling for the information handling system based on a cooling profile provided by a cooling table. The cooling level estimator may determine status information for the information handling system, and provide a quality of service (QOS) level indication to the cooling device controller. The cooling device controller may modify the cooling profile based on the QoS level indication.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating an information handling system according to an embodiment of the present disclosure;

FIG. 2 is a graph illustrating a cooling profile for an information handling system as may be known in the art;

FIGS. 3 and 4 are graphs illustrating cooling profiles for the information handling system of FIG. 1; and

FIG. 5 is a block diagram illustrating a generalized information handling system according to another embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

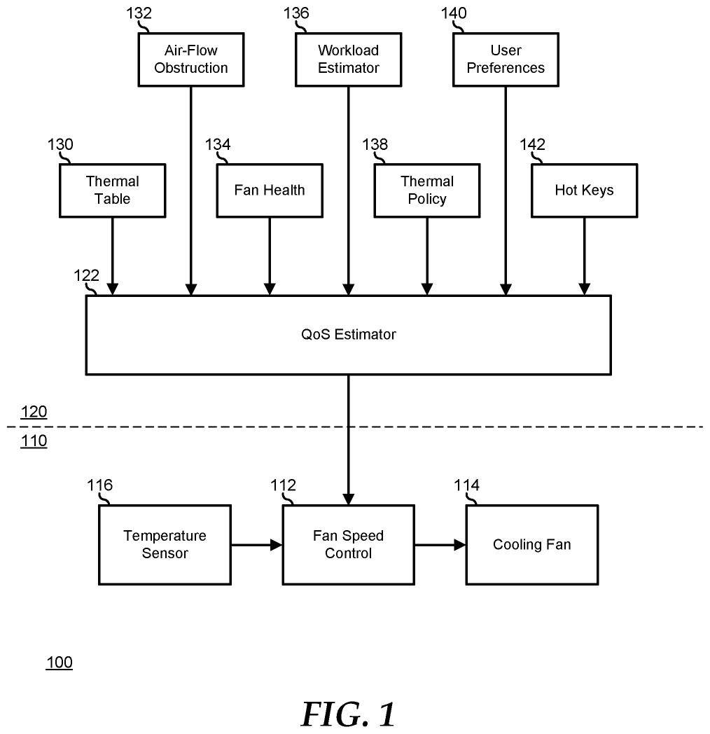

FIG. 1 illustrates an information handling system 100 including a hardware layer 110 and an operating environment 120. Hardware layer 110 includes a fan speed control module 112, a cooling fan 114, and a temperature sensor 116. Cooling fan 114 represents one or more air handling devices that are configured to provide an airflow of chilled air over the components of information handling system 100, such as over processors, chipset components, memory modules, add-in cards, and the like. Temperature sensor 116 represents one or more temperature probes located at various locations within the enclosure of information handling system 100 that provide temperature information to fan speed control module 112 from the associated location. Note that while the current embodiments are described with respect to a cooling fan and air handling devices, this is not necessary, and cooling fan 114 may likewise represent other types of cooling devices, such as liquid cooling systems, or the like, as needed or desired.

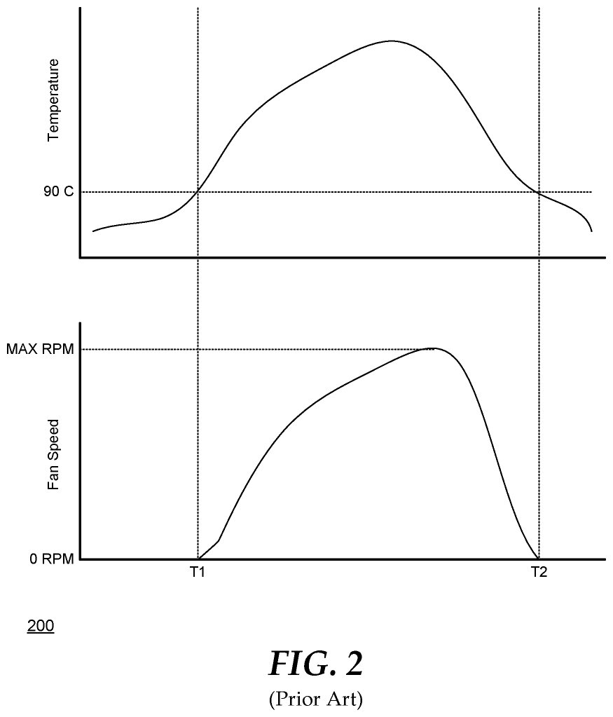

In a typical information handling system, a fan speed controller receives temperature information from one or more temperature sensor, and evaluates the temperature against a thermal table that includes temperature entries and the associated fan speed that is needed to provide sufficient cooling to the information handling system. For example, FIG. 2 illustrates a temperature profile for the temperature information from a temperature sensor in a top graph, and the associated fan speed in a bottom graph. When the temperature of the information handling system is below 90 C, then the fan speed is set at zero (0) revolutions per minute (RPM). When the temperature exceeds 90 C at a time (T1), the fan speed control module begins to ramp up the fan speed, and when the temperature falls, the fan speed control module ramps down the fan speed. Finally when the temperature falls below 90 C at a time (T2), the fan speed is set to zero (0) RPM.

Returning to FIG. 1, operating environment 120 represents elements of information handling system 100 that are instantiated on the hardware of the information handling system. for example, operating environment 120 may represent elements such as a Basic Input/Output System/Universal Extensible Firmware Interface (BIOS/UEFI) or an operating system (OS) instantiated on a CPU of information handling system 100, a management environment instantiated on a baseboard management controller (BMC) of the information handling system, or the like. Operating environment 120 includes a Quality-of-Service (QOS) estimator 122, a thermal table 130, an airflow obstruction detection module 132, a fan health analysis module 134, a workload estimation module 136, a thermal policy management module 138, various user preference settings 140, and various user activated hot keys 142.

Thermal table 130 represents a thermal table similar to the thermal table described above with respect to prior art information handling systems. Airflow obstruction detection module 132 operates to detect whether the airflow created by cooling fan 114 is obstructed, such as through the aggregation of dust particles within information handling system 100, the blockage of airflow vents of the information handling system, or the like. Fan health analysis module 134 operates to determine the operating efficiency of cooling fan 114, and in particular, to detect when various factors, such as fan age, dust buildup, or the like, makes the cooling fan operate at a less efficient level than when the cooling fan is new. Further, fan health analysis module 134 operates to monitor the rate at which cooling fan 114 accelerates from a lower fan speed to a higher fan speed, and to determine when the rate of acceleration decreases due to age, obstructions, dust buildup, or the like.

Workload estimation module 136 operates to estimate a thermal load on information handling system 100 due to the instantiation of the workloads on the information handling system. For example, workload estimation module 136 may determine that various programs are associated with known increases in the thermal load on information handling system 100, may determine that various programs provide cyclic or periodic increases in their thermal loads, or otherwise estimate the future cooling demands on the information handling system based upon the instantiated workloads. Thermal policy management module 138 operates to implement various thermal policies based upon the operating conditions of information handling system 100, for example, due to changes in user preference settings 14, or user activated hot keys 142.

It has been understood by the inventors of the current embodiments that the static cooling scheme based on a thermal table vector, as described above in a typical information handling system may be insufficient to adequately account for other factors affecting cooling efficiency. For example, the rate at which a cooling fan reaches to target speed may change with time due to the mechanical properties of the fan, like bearing wear or other age-related issues, due to secondary factors, like dust build-up or other secondary factors. Typically, an older, more dusty cooling fan ramps up to the target speed more slowly, and the maximum speed of such a cooling fan may be reduced over a newer cooling fan.

In another example, external factors such as airflow blockage, due to dust build-up, or external objects blocking air inlets or outlets, and system modes, such as a laptop computer being operated in a clamshell mode, a tablet mode, or a tent mode, may affect cooling efficiency of the cooling fan. In yet another example, the workloads instantiated on the information handling system may be characterized as providing time varying heat loads on the information handling system. For example, a particular workload execution may increase the temperature of the information handling system for a short duration but may level off or decrease after a few seconds, and such a workload may not necessitate an increase in the cooling fan target speed to accommodate the temporary temperature increase. Thus, it has been understood that the typical thermal table-driven cooling fan behavior may lead to reduced efficiency and impact the QoS provided by the information handling system, and may negatively impact the user experience.

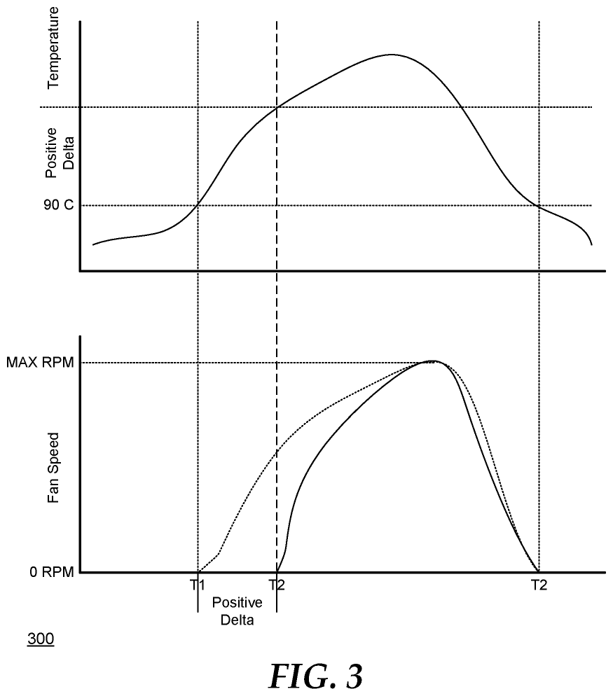

QoS estimator 122 operates to provide adjustments to the fan speed target for fan speed control module 112 based upon the inputs received from thermal table 130, airflow obstruction detection module 132, fan health analysis module 134, workload estimation module 136, thermal policy management module 138, user preference settings 140, and user activated hot keys 142. In a first case, QoS estimator 122 determines that no external factors are affecting fan efficiency. For example, QoS estimator 122 may determine that the fan is new and clean, that no airflow obstructions are detected, that workload thermal profiles are consistent, that the operating mode of information handling system 100 places no particular cooling burden on the cooling system, that user preferences and selections are all set for normal cooling operations. In this case, QoS estimator 122 operates to delay the trigger point for cooling fan 114. FIG. 3 illustrates this first case. The temperature profile for the temperature information from a temperature sensor as shown in FIG. 2 is shown in a top graph, and the associated fan speed target is shown in a bottom graph.

QoS estimator 122 operates to delay the cooling profile provided by cooling fan 114. In a first case QoS estimator 122 operates to add a time delay to the initiation of cooling to a time (T2) that is later than the time T1 when the temperature exceeds 90 C at a time (T1). In this way, QoS estimator 122 operates to increase the efficiency of the cooling of information handling system 100. Such efficiency increase can be seen as the difference in cooling effort provided by the current embodiments (as depicted by the solid line in the bottom graph) as compared to the cooling effort provided by the typical thermal table-based cooling (as depicted by the dotted line in the bottom graph). In another case, QoS estimator 122 operates to increase the temperature threshold for the initiation of cooling by cooling fan 114, as shown by the positive temperature delta.

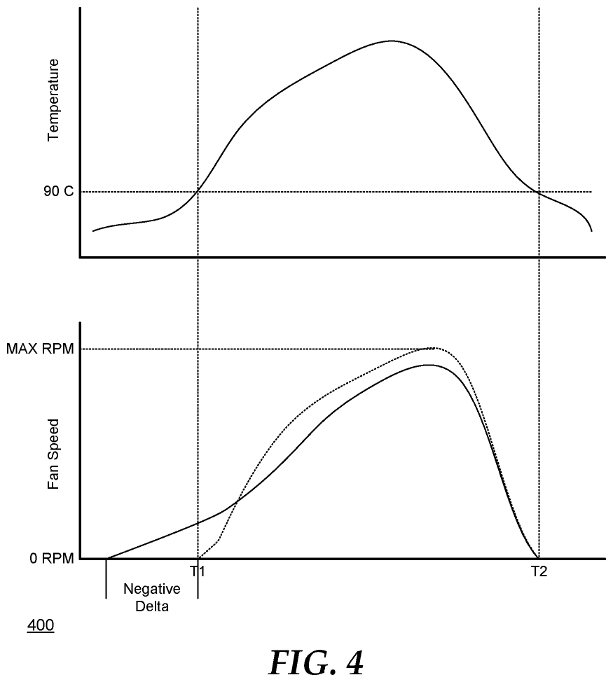

In another case, QoS estimator 122 determines that one or more external factor is affecting fan efficiency. For example, QoS estimator 122 may determine that the fan is old or dirty, that an airflow obstruction is detected, that workload thermal profiles are varying, that the operating mode of information handling system 100 necessitates enhanced cooling of the information handling system, that user preferences and selections are all set for enhanced cooling operations, or the like. In this case, QoS estimator 122 operates to accelerate the trigger point for cooling fan 114. FIG. 4 illustrates this first case. The temperature profile for the temperature information from a temperature sensor as shown in FIG. 2 is shown in a top graph, and the associated fan speed target is shown in a bottom graph. QoS estimator 122 operates to accelerate the cooling profile provided by cooling fan 114, and to start the operation of cooling fan 114 earlier than would otherwise be.

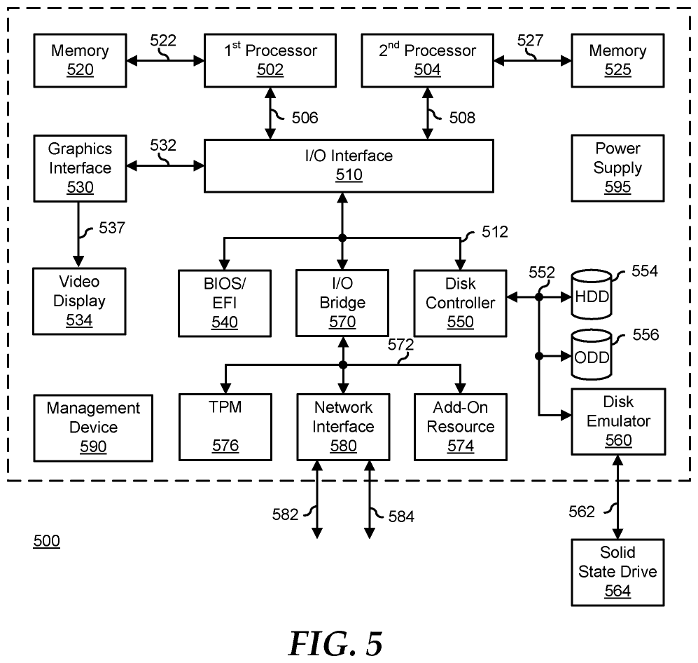

FIG. 5 illustrates a generalized embodiment of an information handling system 500 similar to information handling system 500. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below, and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 562, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 562, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532, and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 1394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512, or can be a different type of interface. As such, I/O bridge 570 extends the capacity of I/O channel 512 where peripheral interface 572 and the I/O channel are of the same type, and the I/O bridge translates information from a format suitable to the I/O channel to a format suitable to the peripheral channel 572 where they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500. Management device 590 can operate off of a separate power plane from the components of the host environment so that the management device receives power to manage information handling system 500 where the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An information handling system, comprising:
a cooling device to cool the information handling system;
a cooling device controller configured to control a level of cooling for the information handling system based on a cooling profile provided by a cooling table; and
a cooling level estimator configured to determine status information for the information handling system, and to provide a quality of service (QOS) level indication to the cooling device controller, wherein the cooling device controller operates to modify the cooling profile based on the QoS level indication.

2. The information handling system of claim 1, wherein the status information includes airflow obstruction information for the information handling system.

3. The information handling system of claim 1, wherein the status information includes health information for the cooling device.

4. The information handling system of claim 1, wherein the status information includes workload information for the information handling system.

5. The information handling system of claim 1, wherein the status information includes thermal policy information for the information handling system.

6. The information handling system of claim 1, wherein the status information includes user preference information for the information handling system.

7. The information handling system of claim 1, further comprising a temperature sensor to provide temperature information for the information handling system, wherein the temperature information provides a vector to the thermal profile.

8. The information handling system of claim 1, wherein in response to a first QoS level indication, the modified cooling profile operates to accelerate cooling of the information handling system by the cooling device.

9. The information handling system of claim 1, wherein in response to a first QoS level indication, the modified cooling profile operates to decelerate cooling of the information handling system by the cooling device.

10. A method, comprising:
providing, in an information handling system, a cooling device to cool the information handling system;
providing, in the information handling system, a cooling device controller;
controlling, by the cooling device controller, a level of cooling for the information handling system based on a cooling profile provided by a cooling table;
determining, by a cooling level estimator, status information for the information handling system;
providing, by the cooling level estimator, a quality of service (QOS) level indication to the cooling device controller; and
modifying, by the cooling device controller, the cooling profile based on the QoS level indication.

11. The method of claim 10, wherein the status information includes airflow obstruction information for the information handling system.

12. The method of claim 10, wherein the status information includes health information for the cooling device.

13. The method of claim 10, wherein the status information includes workload information for the information handling system.

14. The method of claim 10, wherein the status information includes thermal policy information for the information handling system.

15. The method of claim 10, wherein the status information includes user preference information for the information handling system.

16. The method of claim 10, further comprising providing temperature information for the information handling system, wherein the temperature information provides a vector to the thermal profile.

17. The method of claim 10 wherein in response to a first QoS level indication, the modified cooling profile operates to accelerate cooling of the information handling system by the cooling device.

18. The method of claim 10 wherein in response to a first QoS level indication, the modified cooling profile operates to decelerate cooling of the information handling system by the cooling device.

19. An information handling system, comprising:
a cooling device to cool the information handling system;
a cooling device controller configured to control a level of cooling for the information handling system based on a cooling profile provided by a cooling table; and
a processor configured to execute code to determine status information for the information handling system, and to provide a quality of service (QOS) level indication to the cooling device controller, wherein the cooling device controller operates to modify the cooling profile based on the QoS level indication.

20. The information handling system of claim 19, wherein the status information includes airflow obstruction information for the information handling system, health information for the cooling device, workload information for the information handling system, thermal policy information for the information handling system, and user preference information for the information handling system.
